(19) United States
(12) Patent Application Publication
(10) Pub. No.: US 2011/0297429 A1
(43) Pub. Date: Dec. 8, 2011

(54) SLIDING CONTACT ASSEMBLY

(76) Inventor: Jean-Pierre Le Solleu, Strasbourg (FR)

(21) Appl. No.: 13/147,874

(22) PCT Filed: Feb. 2, 2010
(86) PCT No.: PCT/EP2010/051249

§ 371 Date: Aug. 25, 2011

(30) Foreign Application Priority Data
Feb. 5, 2009 (EP) 09152117.9

(51) Int. Cl. H05K 1/09; H01R 9/00

(52) U.S. Cl. 174/257; 29/842

(57) ABSTRACT

A sliding contact assembly includes a printed circuit board having a substrate on which is arranged at least one contact pad. The at least one contact pad is made of several layers including a thin external layer essentially made of gold. The gold layer is deposited on the at least one contact pad through a gold flash type process. The assembly also includes a movable contact element including a support member. The support member has a contact surface provided with a protective coating and the contact surface is biased against the said contact pad when the movable contact element is moved in relation to the contact pad. The protective coating includes a palladium alloy layer. Methods to manufacture a sliding contact assembly are also presented.

### CROSS-REFERENCE TO RELATED APPLICATION

This application claims the benefit under 35 U.S.C. §371 of published PCT Patent Publication No. PCT/EP2010/051249, filed on 2 Feb. 2010, which claims priority to EP 09152117.9 filed on 5 Feb. 2009, the entire disclosure of which is hereby respectively incorporated by reference herein.

### TECHNICAL FIELD

The present invention relates generally to sliding contact assemblies for low current applications.

### BACKGROUND OF INVENTION

The present invention relates more particularly to a sliding contact assembly to be implemented in a vehicle. One such example is in the column integrated module (CIM) arranged on the steering column of the vehicle used for electrical connection of switch devices.

Automotive suppliers have used printed circuit boards (PCB) having gold plating pads as direct contact interface for low current sliding contacts. Several gold plating processes are available on the market, providing various wear behavior.

Galvanic hard gold electroplated PCBs provide performance and contact reliability for low current applications, but galvanic hard gold electroplating is also the most expensive technology. This type of plating generates extra costs due to the quantity of gold necessary and due also to the process complexity.

In a cost driven industry, it is required to use a cheaper solution using standard low cost PCBs while still providing high reliability and good performance. To manufacture standard low cost PCBs with contact pads, several gold plating processes are available on the market including Electroless Nickel Immersion Gold (ENIG) and electrolytic pattern flash gold. These two processes provide a very thin layer of gold, generally lower than 0.150 μm. These two gold plating processes will be designated in the following description under the general term “gold flash process.” PCBs that include a protective layer of gold deposited according to a gold flash process will be named as gold flash PCBs.

Gold flash PCBs are generally designed to provide an oxidization/corrosion protection for the contact pads on the PCB to ensure a safe soldering of the electronic components. It is initially not designed as a contact interface.

Due to the very low thickness of gold deposited on the contact surface, the gold flash layer is not sufficient to provide long term reliable contact resistance without additional protection. The gold flash layer is porous and exhibits the underneath nickel layer through pores. It may generate an oxide and increase the electric contact resistance. To avoid corrosion or oxidization of the nickel, contact grease with specific protection properties is used.

The main problem with the use of gold flash PCBs is the wear behavior with an extreme sensitivity of gold, even when hardened with cobalt or nickel.

Up to now, the contact sliders used in sliding contact assemblies are made of a bronze-based contact spring which is electroplated with a nickel under layer and a gold cobalt protective layer. When such gold plated contact sliders are used on gold flash PCBs, the lifetime is too short and some reliability problems may occur. To increase sliding contact assembly lifetime it is necessary to use gold flash PCBs with very high requirements in term of roughness, in view to minimize friction at the contact interface. Such roughness requirements are very difficult to comply with and it increases PCB cost.

### SUMMARY OF THE INVENTION

The purpose of the present invention is to solve the above mentioned problem by providing a reliable and low cost solution to build sliding contact assemblies.

For this purpose, the present invention proposes a sliding contact assembly for low current applications. The sliding assembly includes:
a printed circuit board including a substrate on which is arranged at least one contact pad made of several layers including a thin external layer essentially made of gold, the gold layer being deposited through a gold flash type process, and
a movable contact element including a support member having a contact surface provided with a protective coating, the contact surface being biased against the contact pad when the movable contact element is moved with regards to the contact pad. The sliding contact assembly is characterized in that the protective coating includes a palladium alloy layer.

Other features of the present invention include:
the contact pad gold layer has a thickness of 0.15 μm or less;
the contact pad gold layer is deposited according to an Electroless Nickel Immersion Gold process;
the palladium alloy includes at least 60% of palladium;
the palladium alloy includes substantially between 70% and 90% of palladium and between 30% and 10% of nickel;
the palladium alloy layer has a thickness between 1 and 3 μm;
the protective coating includes a nickel under layer on which the palladium alloy layer is deposited;
the protective coating includes a gold layer which is deposited on the palladium alloy layer through a gold flash type process;
the support member is made of copper alloy; and
a film of grease material is deposited above the contact pad in order to ease the sliding of the contact surface on the contact pad.

The present invention also proposes a manufacturing method for a sliding contact assembly for low current applications. The method includes the following steps:
providing a PCB substrate with at least one contact pad wherein the upper external layer is made essentially of gold deposited through a gold flash type process,
providing a movable contact element including a support member having a contact surface to be biased against the contact pad,
coating the contact surface with a protective coating, and
providing a film of grease material at the contact interface between the contact pad and the movable contact element. The manufacturing method is characterized in that the coating step includes forming a palladium alloy layer.

### BRIEF DESCRIPTION OF THE DRAWINGS

The present invention is now described by way of example with reference to the accompanying drawings in which:

FIG. 1 is a schematic view showing a sliding contact assembly according to the present invention including a movable contact element; and

FIG. 2 is an enlarged cross-section view showing a portion of the contact surface of the movable contact element of FIG. 1.

### DETAILED DESCRIPTION

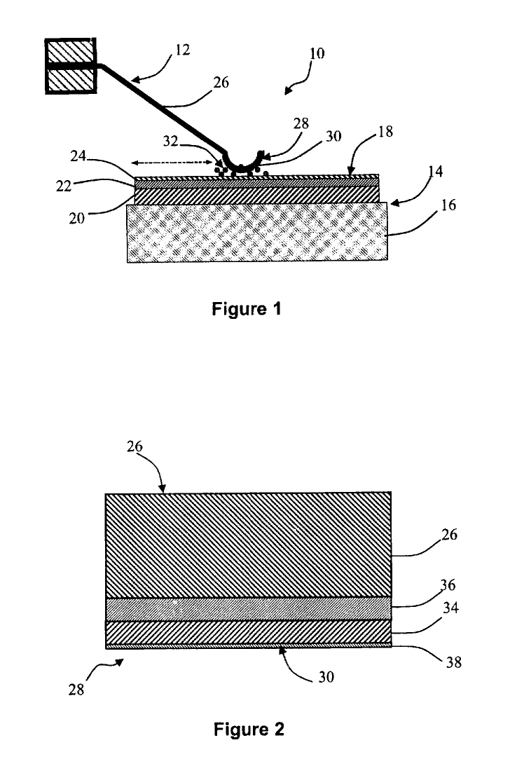

FIG. 1 shows a sliding contact assembly 10 for low current applications built according to a preferred embodiment of the present invention. The sliding contact assembly 10 includes a movable contact element 12 which is movable along a longitudinal direction X relatively to a printed circuit board (PCB) 14.

PCB 14 includes a substrate 16 on which is arranged at least one contact pad 18 made of several layers. According to the embodiment shown on FIG. 1, the contact pad 18 is constituted, from the upper surface of the substrate upwards of:
a base layer 20 of copper, for example 35 μm thick,
an intermediate layer 22 of nickel, preferably 3 to 6 μm thick, and
an external layer 24 essentially made of gold, preferably 0.15 μm thick or less.

As may be seen, the external layer 24 of gold is made very thin, compared to the two other layers. It may be made of gold alloy hardened with cobalt (AuCo) or Nickel (AuNi).

Advantageously, the external layer 24 is deposited through a gold flash process, preferably an Electroless Nickel Immersion Gold process. Alternatively, the external layer is deposited according to an Electrolytic Pattern Plating process.

The movable contact element 12, or slider, includes a support member 26 in the shape of a spring blade having a contact surface 28 provided with a protective coating 30 shown on FIG. 2. Thanks to the spring blade shape of the support member 26, the contact surface 28 is biased against the contact pad 18 of the PCB 14 when the movable contact element 12 is moved with regards to the contact pad 18.

The support member 26 is preferably made of bronze (copper-tin alloy CuSn). Alternatively, the support member could be made of another copper alloy such as copper-beryllium alloy or copper-nickel alloy.

Advantageously, a film 32 of grease material is deposited above the contact pad 18, at the contact interface between the contact pad 18 and the contact surface 28, in order to ease the sliding of the contact surface 28 on the contact pad 18. The grease is chosen in order to provide a good oxidization protection for the nickel under layer 22 and to allow the contact functionality at temperatures down to −40° C. The grease material is preferably a perfluorpolyester-based (PFPE) grease.

According to the present invention, the protective coating 30 on the contact surface 28 includes a layer 34 of palladium alloy including at least 60% of palladium. Advantageously, the palladium alloy is constituted substantially of 80% palladium and 20% nickel. Preferably, the layer 34 of palladium alloy has a thickness between 2 and 3 μm and is deposited through an electrolytic process.

According to the preferred embodiment, the protective coating 30 includes an under layer 36 of nickel on which the layer 34 of palladium alloy is deposited.

Optionally, the protective coating 28 includes an additional layer 38 of gold which is deposited on the layer 34 of palladium alloy through a gold flash-type process. The additional layer 38 is preferably 0.05 μm to 0.1 μm thick and has a cosmetic purpose as well as an oxidization protection purpose.

Endurance tests have been implemented with sliding contact assemblies 10 made according to the present invention and they have shown a significant improvement in wear resistance compared to sliding contact assemblies using gold for the protective coating instead of palladium alloy. The lifetime of the sliding contact assembly has been increased from a factor 200 on a given PCB.

Now a method for manufacturing a sliding contact assembly according to the present invention will be described. The method includes the following steps:
providing a PCB substrate with at least one contact pad wherein the upper external layer is made essentially of gold deposited through a gold flash 30 type process,
providing a movable contact element including a support member having a contact surface to be biased against the contact pad,
coating the contact surface with a protective coating, and
providing a film of grease material at the contact interface between the contact pad and the movable contact element.

According to the present invention, the coating step includes the following steps:
plating the contact surface with an under layer of nickel, and
plating the under layer of nickel with a layer of palladium alloy.

Optionally, the coating step may include an additional step of plating the layer of palladium with an additional layer of gold through a gold flash type process.

1. A sliding contact assembly for low current applications, comprising:
a printed circuit board including a substrate on which is arranged at least one contact pad made of several layers including a thin external layer essentially made of gold, said gold layer being deposited through a gold flash type process; and
a movable contact element including a support member having a contact surface provided with a protective coating, said contact surface being biased against said contact pad when the movable contact element is moved in relation to said contact pad,
wherein said protective coating includes a palladium alloy layer.

2. The assembly according to claim 1, wherein said contact pad gold layer has a thickness of 0.15 μm or less.

3. The assembly according to claim 1, wherein said contact pad gold layer is deposited according to an Electroless Nickel Immersion Gold process.

4. The assembly according to claim 1, wherein said palladium alloy comprises at least 60% of palladium.

5. The assembly according to claim 1, wherein said palladium alloy comprises substantially between 70% and 90% of palladium and between 30% and 10% of nickel.

6. The assembly according to claim 1, wherein said palladium alloy layer (34) has a thickness between 2 and 3 μm.

7. The assembly according to claim 1, wherein said protective coating includes a nickel underlayer on which said palladium alloy layer is deposited.

8. The assembly according to claim 1, wherein said protective coating includes a gold layer which is deposited on said palladium alloy layer through a gold flash type process.

9. The assembly according to claim 1, wherein said support member is made of copper alloy.

10. The assembly according to claim 1, wherein a film of grease material is deposited above said contact pad in order to ease the sliding of said contact surface on said contact pad.

11. A method to manufacture a sliding contact assembly, comprising:
providing a printed circuit board (PCB) substrate with at least one contact pad wherein the upper external layer is made essentially of gold deposited through a gold flash type process,
providing a movable contact element including a support member having a contact surface to be biased against said contact pad,
coating said contact surface with a protective coating,
providing a film of grease material at the contact interface between said contact pad and said movable contact element,
wherein that said coating step includes forming a palladium alloy layer.

12. A method of manufacturing a sliding contact assembly, comprising:
providing a printed circuit board (PCB) that includes a substrate having at least one contact pad, the at least one contact pad being composed of a plurality of layers;
depositing an external layer in the plurality of layers of the at least one contact pad formed from at least one of,
(i) gold, and
(ii) gold alloy
through a gold-flash process; and
providing a moveable contact element that includes a support member configured to electrically engage with the external layer of the at least one contact pad.

13. The method according to claim 12, wherein the step of depositing the external layer on the at least one contact pad is applied by an electroless nickel immersion gold process.

14. The method according to claim 12, wherein the step of depositing the external layer on the at least one contact pad is applied by an electrolytic pattern plating process.

15. The method according to claim 12, wherein the at least one contact pad has a layer of nickel that underlies the external layer.

16. The method according to claim 15, wherein the at least one contact pad further has a layer of copper that underlies the layer of nickel.

17. The method according to claim 12, wherein the support member includes an external surface that is configured to engage the external surface of the at least one contact pad, and the method further includes,
depositing at least one of,
(i) gold, and
(ii) gold alloy
through a gold flash process to form the external layer of the support member.

18. The method according to claim 17, wherein the support member includes,
a layer of palladium alloy that underlies the external layer of the support member.

19. The method according to claim 18, wherein the support member further includes,
a nickel layer that underlies said palladium alloy layer.

20. The method according to claim 19, wherein the support member further includes,
a copper alloy that underlies said nickel layer.

21. The method according to claim 12, further including,
depositing a film of grease intermediate the external layer of the at least one contact pad and the support member.

22. The method according to claim 12, wherein the step of depositing the film of grease includes the grease being a perflourpolyester (PFPE) grease.

23. A sliding contact assembly comprising:
a printed circuit board (PCB) including a substrate having at least one contact pad arranged thereon, said at least one contact pad includes a plurality of layers where an external layer is formed from one of gold and gold alloy deposited thereon by a gold flash process; and
a movable contact element including a support member having a protective coating disposed thereon and formed from one of gold and gold alloy deposited to the support member by the gold-flash process, the protective coating further including a contact surface,
wherein when the moveable contact element moves relative to the at least one contact pad the contact surface of the support member electrically biases against the external layer of the at least one contact pad.

24. The assembly according to claim 23, wherein the gold flash process is an electroless nickel immersion gold process.

25. The method according to claim 23, wherein the gold flash process is an electrolytic pattern plating process.
